(19) United States
(12) Patent Application Publication
(10) Pub. No.: US 2012/0043869 A1
(43) Pub. Date: Feb. 23, 2012

(54) SERVER RACK

(75) Inventors: JUN LIU, Shenzhen City (CN); JIAN-GANG XIAO, Shenzhen City (CN); ZHAO-GUO WEN, Shenzhen City (CN); CHUN-HSIEN LIN, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/076,320

(22) Filed: Mar. 30, 2011

(30) Foreign Application Priority Data
Aug. 18, 2010 (CN) 201010256325.8

(51) Int. Cl. H05K 7/18

(52) U.S. Cl. 312/223.2

(57) ABSTRACT

A server rack includes a frame, a support, and a securing member. The frame includes a first pole and a second pole connected to the first pole. The support is connected to the first pole and the second pole. The securing member includes a first fastening section, a second fastening section connected to the first fastening section, and a third fastening section connected to the first fastening section and the second fastening section. The first fastening section is received in the first pole, the second fastening section is received in the second pole, and the third fastening section is received in the support. The first fastening section and the second fastening section are located on a first plane, and the third fastening section is located on a second plane substantially perpendicular to the first plane. The first fastening section, the second fastening section, and the third fastening section share a base wall.

### BACKGROUND

1. Technical Field

The present disclosure relates to a server rack.

2. Description of Related Art

A server rack houses electronic equipment, such as network server systems, data storage devices, and power supplies. A server rack generally includes two frames with the same configuration and four supports connected to the two frames. Each frame includes a first pole and a second pole. The first pole is often secured to the second pole and the supports by jointing, this is very inconvenient.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of a server rack in accordance with an embodiment.

FIG. 2 is an exploded, cutaway view of a server rack in accordance with an embodiment.

FIG. 3 is similar to FIG. 2, showing in a different aspect.

FIG. 4 is similar to FIG. 3, showing in a different aspect.

FIG. 5 is an isometric view of a securing member of the server rack.

FIG. 6 is similar to FIG. 4, showing in a different aspect.

FIG. 7 is an isometric, cutaway view of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

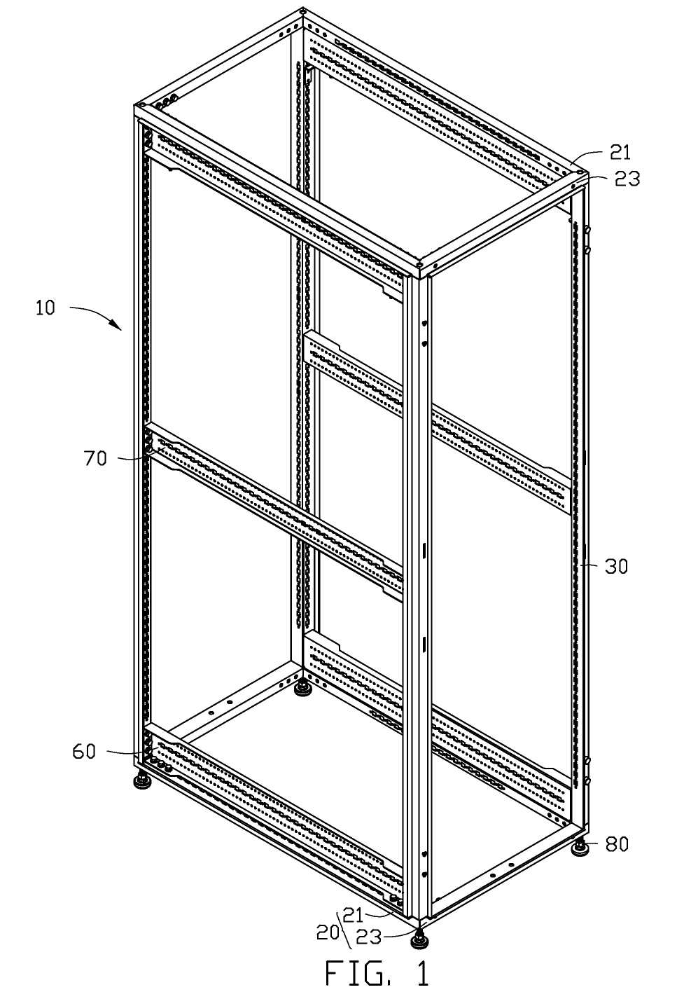

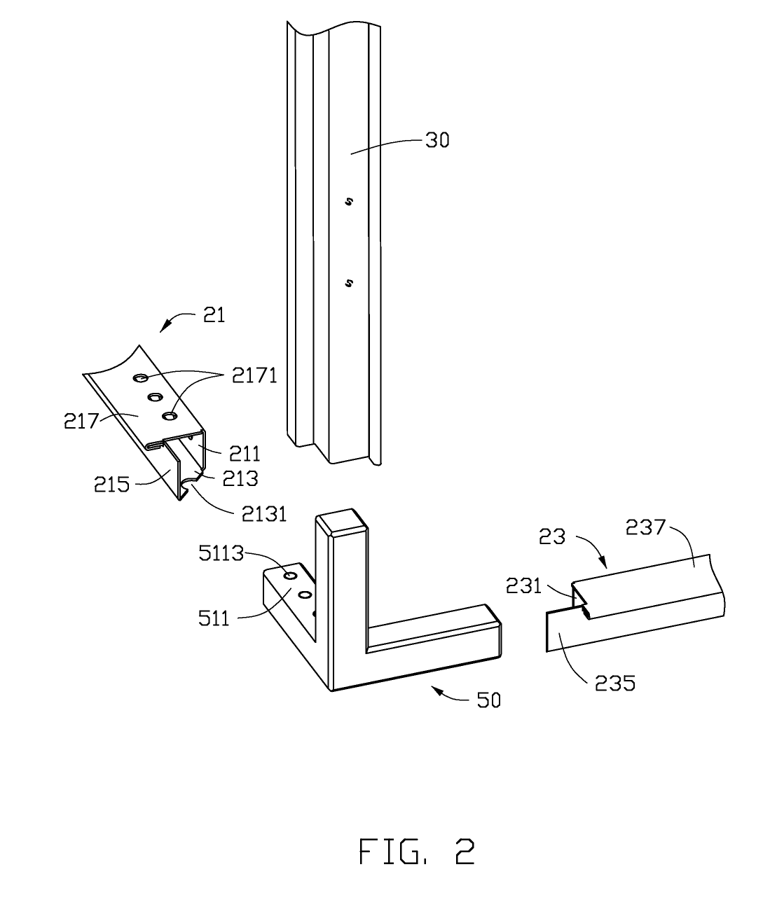

Referring to FIG. 1, a server rack in accordance with an embodiment includes two frames 20, four supports 30 located between the two frames 20, a plurality of securing members 50 (see FIG. 2), two first parallel connecting members 60, two second parallel connecting members 70, and four legs 80.

Each frame 20 includes two parallel first poles 21, and two parallel second poles 23. In one embodiment, each frame 20 is a rectangle, each first pole 21 is substantially perpendicular to each second pole 23, and each of the first and second poles 21, 23 is substantially perpendicular to the supports 30.

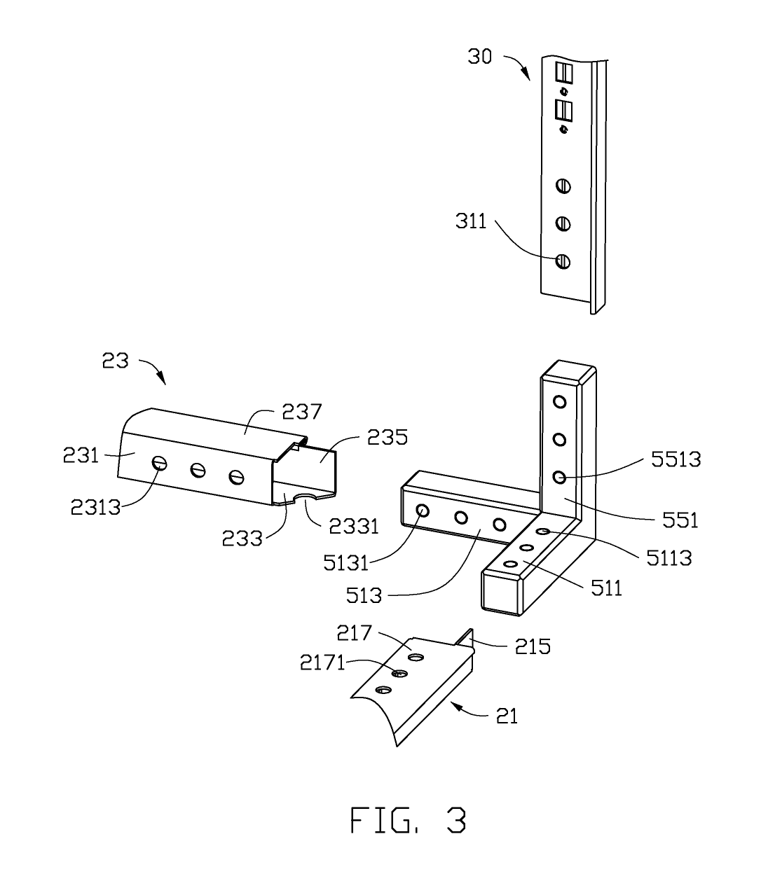

Referring to FIGS. 2-4, each first pole 21 includes a first base 213, a first side panel 211, a top panel 217, and a second side panel 215 connected two opposite edges of the first base 213. A first notch 2131, such as a semicircle cutout, is defined in the first base 213. Three mounting holes 2113 are defined in the first side panel 211, and three fixing holes 2171 are defined in the top panel 217.

Each second pole 23 includes a second base 233, a first side plate 231, a top plate 237, and a second side plate 235 connected to two opposite edges of the second base 233. A second notch 2331, such a semicircle cutout, is defined in the second base 233. The second notch 2331 has the same size as that of the first notch 2131, so that the second notch 2331 and the first notch 2131 together define a circle hole. Three securing holes 2313 are defined in the first side plate 231.

A plurality of first connecting holes 310 is defined in a first side wall of each support 30. Three second connecting holes 311, located on the bottom, are defined in a second side wall adjacent to the first side wall of the support 30.

Each securing member 50 includes a first fastening section 51 configured for being received in the first pole 21, a second fastening section 53 configured for being received in the second pole 23, and a third fastening section 55 configured for being received in the support 30. The first and second fastening sections 51, 53 are located on a first plane, and the third fastening section 55 is located on a second plane that is substantially perpendicular to the first plane. The first, second and third fastening sections 51, 53, 55 have a same configuration. A positioning hole 571 with an inner thread is defined in the securing member 50. In one embodiment, the positioning hole 571 is located in at joint of the first, second and third fastening sections 51, 53, 55, and the first, second and third fastening sections 51, 53, 55 share a base wall 57. The base wall 57 is configured for engaging with the first base 213, of the first pole 21, and the second base 233, of the second pole 23.

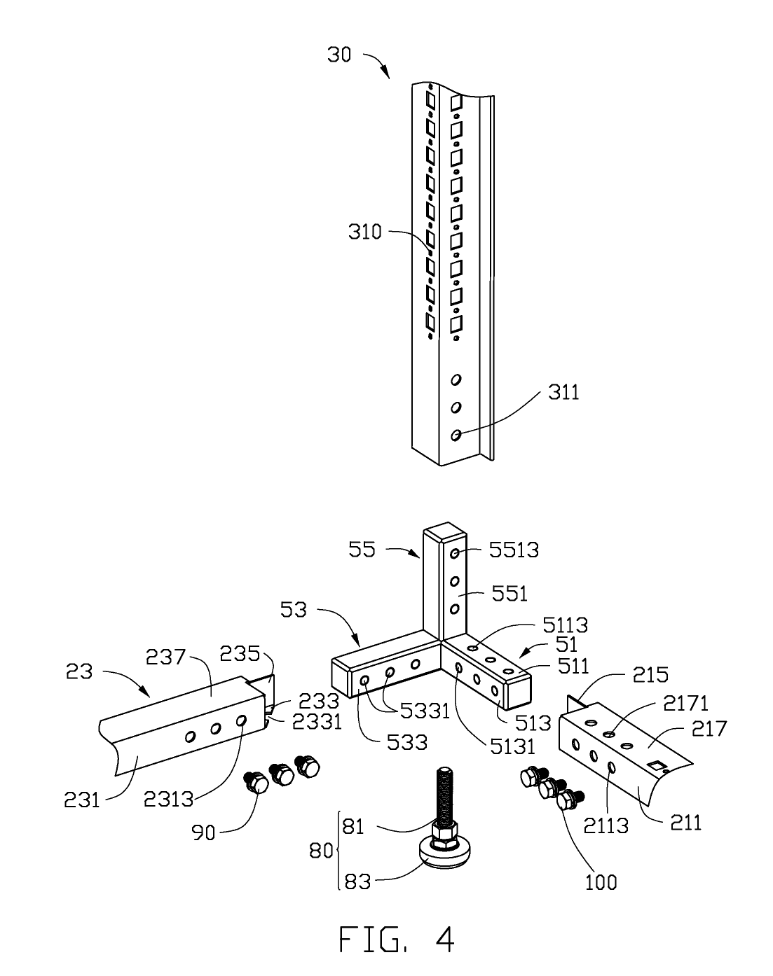

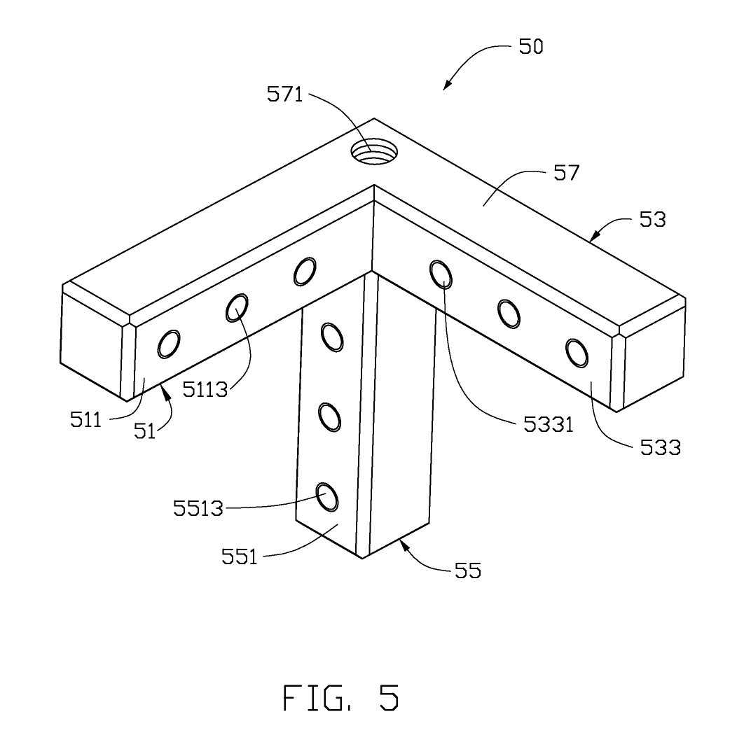

Referring to FIGS. 4-5, the first fastening section 51 includes a top board 511 and a first side board 513 substantially perpendicular to the top board 511. Three retaining holes 5113, corresponding to the three fixing holes 2171 of the top panel 217, are defined in the top board 511. Three fastening holes 5131, corresponding to the three mounting holes 2113 of the side panel 211, are defined in the side board 513. The second fastening section 53 includes a second side board 533 that is substantially perpendicular to the first side board 513. Three locking holes 5331 are defined in the second side board 533, and the three locking holes 5331 correspond to the three securing holes 2313. The third fastening section 55 includes a third side board 551 substantially perpendicular to the top board 511. Three receiving holes 5513 are defined in the third side board 551, corresponding to the three second connecting holes 311 of the support 30.

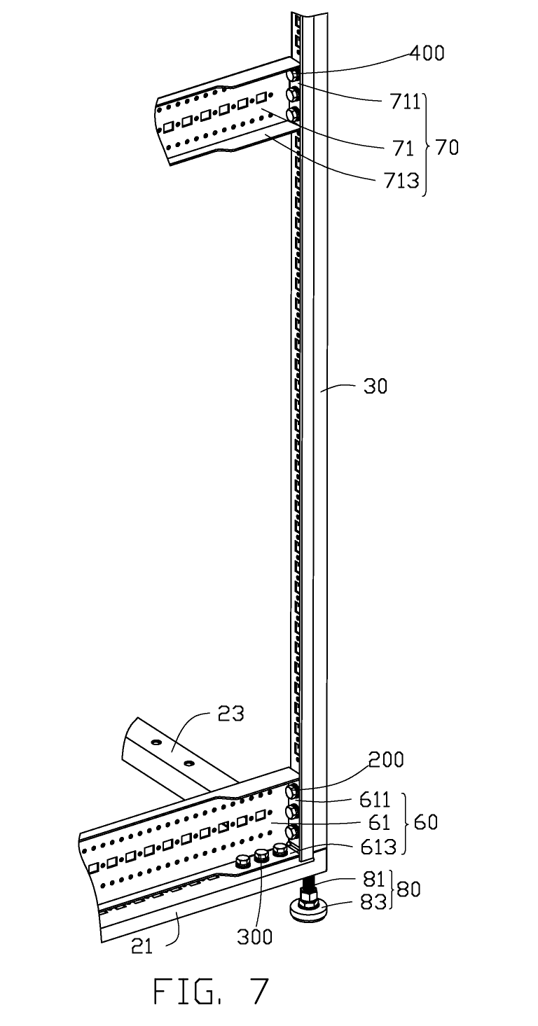

Referring to FIG. 7, the first connecting member 60 has the same configuration as the second connecting member 70. Each first connecting member 60 includes a main body 61, a first flanges 611 connected to the main body 61, and two parallel second flanges 613 connected to the main body 61. Each second connecting member 70 includes a main body 71, a first flanges 711 connected to the main body 71, and two parallel second flanges 713 connected to the main body 71. Three first through holes (not shown) are defined in each first flange 611, 711, corresponding to the plurality of first connecting holes 310 of the support 30. Three second though holes (not shown) are defined in one of the two second flange 613, 713, corresponding to the retaining holes 5113 and the fixing holes 2171.

Each leg 80 includes a foot 83 and a fixing shaft 81 connected to the foot 83. The fixing shaft 81 has an outer thread, configured to be screwed into the positioning hole 571 of the securing member 50.

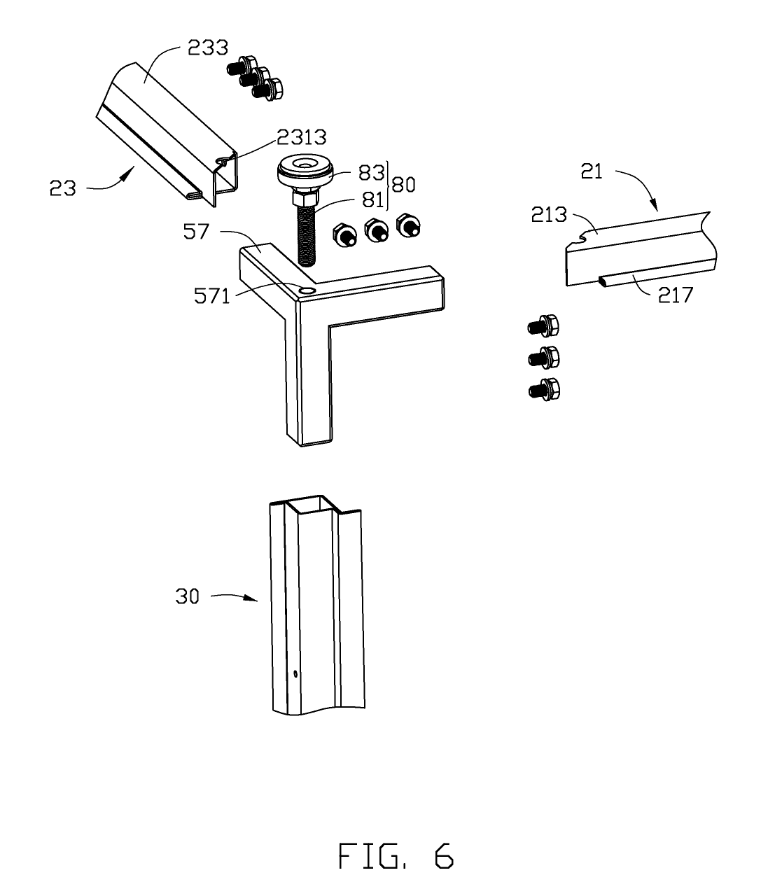

Referring to FIGS. 4, 6-7, in assembly, the first pole 21 is substantially perpendicularly to the second pole 23. The first fastening section 51 of the securing member 50 is received in the first pole 21, the second fastening section 53 of the securing member 50 is received in the second pole 23, and the third fastening section 55 of the securing member 50 is received in the support 30. The locking holes 5331 of the second side board 533 are aligned with the securing holes 2313 of the first side plate 231. Three first fasteners 90 are engaged into the locking holes 5331 and the securing holes 2313, for securing the second side board 533 to the first side plate 231. The fastening holes 5131 of the first side board 513 are aligned with the mounting holes 2113 of the first side panel 211. Three second fasteners 100 are inserted into the fastening holes 5131 and the mounting holes 2113, so the first side board 513 is secured to the first side panel 211.

The first connecting member 60 is located between the two supports 30. The first flange 611 abuts the support 30, and the second flange 613 abuts the top panel 217 of the first pole 21. The first through holes of the first flange 611 are aligned with first connecting holes 310 of the support 30, three third fasteners 200 are inserted into the first through holes and the connecting holes 310. Thus, the first flange 611 is mounted to the support 30. The second through holes, of the second flange 613, are aligned with the fixing holes 2171, of the first pole 21, and the retaining holes 5113, of the first fastening section 51. Three fourth fasteners 300 are received in the second through holes, the fixing holes 2171 and the retaining holes 5113. Therefore, the support 30 is mounted to the first fastening section 51 and the first pole 21. Then, a close hole (not shown), for example, a circle hole is defined by the first notch 2131 and the second notch 2331, for receiving the fixing shaft 81 of the leg 80.

The second connecting member 70 is located between the two supports 30, and substantially parallel to the first connecting member 60. The first flange 711 abuts the support 30. Three fifth fasteners 400 are passed through the first through holes of the first flange 711 and the first connecting holes 310 of the support, to secure the first flange 711 to the support 30.

The fixing shaft 81 of the leg 80 is passed through the round hole, and screwed into the positioning hole 571 of the securing member 50. Therefore, the leg 80 is mounted to the securing member 50, and the server rack assembly can be assembled stably.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A server rack comprising:
a frame comprising a first pole and a second pole connected to the first pole;
a support connected to the first pole and the second pole; and
a securing member comprising a first fastening section, a second fastening section connected to the first fastening section, and a third fastening section connected to the first fastening section and the second fastening section; the first fastening section and the second fastening section located on a first plane, the third fastening section located on a second plane substantially perpendicular to the first plane; and the first fastening section, the second fastening section, and the third fastening section share a base wall;
wherein the first fastening section is received in the first pole, the second fastening section is received in the second pole, and the third fastening section is received in the support.

2. The server rack of claim 1, wherein the first fastening section is substantially perpendicular to the second fastening section and the third fastening section.

3. The server rack of claim 1, wherein the first fastening section, the second fastening section, and the third fastening section have a same configuration.

4. The server rack of claim 3, wherein the first fastening section is a cuboid.

5. The server rack of claim 3, wherein the first fastening section comprises a first side board, and the first side board is attached to a first side panel of the first pole.

6. The server rack of claim 1, further comprising a leg, a positioning hole defined in the base wall, and the leg is engaged in the positioning hole.

7. The server rack of claim 6, wherein the positioning hole is located on a joint connected to the first fastening section, the second fastening section and the third fastening section.

8. The server rack of claim 6, wherein the leg comprises a foot and a fixing shaft connected to the foot, and the fixing shaft is received in the positioning hole.

9. The server rack of claim 8, wherein a first notch is defined in a first base of the first pole, a second notch is defined in a second base of the second pole, and a close hole is defined by the first notch and the second notch and engaged with the fixing shaft .

10. The server rack of claim 1, further comprising a first connecting member; the first connecting member comprises a main body, a first flange and a second flange; the first flange is attached to the support, and the second flange is attached to the first pole.

11. A server rack comprising:
a frame comprising a first pole and a second pole connected to the first pole;
a support substantially perpendicular to the first pole and the second pole, the first pole comprising a first base, and the second pole comprising a second base; and
a securing member comprising a first fastening section, a second fastening section connected to the first fastening section, and a third fastening section connected to the first fastening section and the second fastening section; the first fastening section is received in the first pole, the second fastening section is received in the second pole; and the third fastening section is received in the support;
wherein the first fastening section, the second fastening section, and the third fastening section shares a base wall, and the base wall is engaged with the first base and the second base.

12. The server rack of claim 11, wherein the first fastening section and the second fastening section are located on a first plane, the third fastening section located on a second plane substantially perpendicular to the first plane.

13. The server rack of claim 11, wherein the first fastening section, the second fastening section, and the third fastening section have a same configuration.

14. The server rack of claim 13, wherein the first fastening section is a cuboid.

15. The server rack of claim 11, wherein the first fastening section comprises a first side board, and the first side board is attached to a first side panel of the first pole.

16. The server rack of claim 11, further comprising a leg, a positioning hole defined in the base wall, and the leg is engaged in the positioning hole.

17. The server rack of claim 16, wherein the positioning hole is located on a joint connected to the first fastening section, the second fastening section and the third fastening section.

18. The server rack of claim 16, wherein the leg comprises a foot and a fixing shaft connected to the foot, and the fixing shaft is received in the positioning hole.

19. The server rack of claim 18, wherein a first notch is defined in the first base of the first pole, a second notch is defined in the second base of the second pole, and a close hole is defined by the first notch and the second notch and engaged with the fixing shaft.

20. The server rack of claim 11, further comprising a first connecting member; the first connecting member comprises a main body, a first flange and a second flange; the first flange is attached to the support, and the second flange is attached to the first pole.
